(19) United States
(12) Patent Application Publication
(10) Pub. No.: US 2012/0071005 A1
(43) Pub. Date: Mar. 22, 2012

(54) HEAT TREATING APPARATUS, HEAT TREATING METHOD AND STORAGE MEDIUM

(75) Inventor: Masahiro SHIMIZU, Nirasaki-shi (JP)

(73) Assignee: TOKYO ELECTRON LIMITED, Tokyo (JP)

(21) Appl. No.: 13/305,379

(22) Filed: Nov. 28, 2011

Related U.S. Application Data
(62) Division of application No. 11/688,485, filed on Mar. 20, 2007.

(30) Foreign Application Priority Data
Mar. 22, 2006 (JP) 2006-077943

(51) Int. Cl. H01L 21/314

(52) U.S. Cl. 438/786; 257/E21.267

(57) ABSTRACT

A heat treating apparatus, which performs a specified heat treatment on a target object, includes a processing chamber accommodating therein the target object; a mounting table for mounting thereon the target object; a vacuum exhaust system for vacuum evacuating the processing chamber; an electromagnetic wave supply unit for irradiating an electromagnetic wave onto the target object to heat the target object; and a controller for controlling the heat treating apparatus such that the electromagnetic wave is irradiated onto the target object at a high vacuum level at which plasma is not generated. Further, a heat treating method performs a specified heat treatment on a target object, wherein the target object is accommodated in a processing chamber capable of being vacuum evacuated, and the target object is heated by irradiating an electromagnetic wave thereon at a high vacuum level at which plasma is not generated in the processing chamber.

### CROSS-REFERENCE(S) TO RELATED APPLICATIONS

This application is a divisional application of pending U.S. application Ser. No. 11/688,485, filed on Mar. 20, 2007, which claims priority to Japanese Patent Application No. 2006-077943 filed on Mar. 22, 2006, the entire contents of both of which are incorporated herein by reference.

### FIELD OF THE INVENTION

The present invention relates to a single-wafer heat treating apparatus, a heat treating method, and a storage medium for performing a specified heat treatment on a semiconductor wafer or the like by irradiating a microwave or a high frequency wave to heat the wafer.

### BACKGROUND OF THE INVENTION

In general, in order to fabricate a desired semiconductor device, various heat treatment processes such as a film forming process, an pattern etching process, a oxidation/diffusion process, a quality modification process or annealing process are repeatedly performed on a semiconductor device. With a recent trend towards high-density, a multilayered structure and high-integration of a semiconductor device, a strict heat treating method has been required; and especially, there have been demands for an enhanced in-surface uniformity and a higher film quality of wafers in various heat treatment processes. For example, after ion-implanting impurity atoms into the channel while processing a channel in a semiconductor device, e.g., a transistor, an annealing process is usually carried out in order to activate the impurity atoms.

In this case, if the annealing process is performed for a long period of time, the atomic structure can be stabilized, but the impurity atoms diffuse deeply in a direction of film thickness to penetrate throughout the channel. Therefore, the annealing process needs to be performed in a short time. That is, in order to stabilize the atomic structure while forming the channel with a thin film thickness without the penetration, it is necessary to rapidly raise the temperature of the semiconductor wafer to a high temperature, and further, after the annealing process, rapidly lower the temperature to a low temperature at which diffusion does not occur.

In particular, recently, a transistor device having a structure in which an extremely minute area such as a source/drain extension is disposed in a channel has been proposed. Accordingly, in order to maintain electrical characteristics of the minute area, it is required for the impurity atoms to be activated without being diffused by the rapid rise and fall in temperature.

For the annealing process, a lamp annealing apparatus using a heating lamp to perform a lamp annealing (see Patent Document 1) and a heat treating apparatus using an LED device or a laser device (see Patent Documents 2 to 4) have been proposed.

However, as is well known, in the fabrication process of the semiconductor integration circuit, various kinds of materials are disposed on the wafer surface thereof. For example, during a transistor fabrication process, minute areas occupied by materials having different optical characteristics such as a silicon oxide film (e.g., a SiO₂ film) serving as an insulating film, a polysilicon film, a Cu or Al film serving as a wiring layer, a TiN film serving as a barrier film or the like are scattered the wafer surface.

In this case, each of the materials has different optical characteristics (i.e., a reflectance, an absorptance, a transmittance and the like) with respect to light used in the annealing process (i.e. a visible ray or an ultraviolet light). Therefore, an amount of absorbed energy varies depending on the type of each material. As a result, due to the variance in the optical characteristics, there are occasions when the annealing process can hardly be performed or cannot be uniformly performed. Therefore, a heating apparatus for heating a semiconductor wafer by using an electromagnetic wave (e.g., a microwave or a high frequency wave whose wavelength is longer than that of a visible ray or an ultraviolet light) has also been proposed (see Patent Documents 5 to 7).

(Patent Document 1) U.S. Pat. No. 5,689,614

(Patent Document 2) Japanese Patent Laid-open Application No. 2004-296245

(Patent Document 3) Japanese Patent Laid-open Application No. 2004-134674

(Patent Document 4) U.S. Pat. No. 6,818,864

(Patent Document 5) Japanese Patent Laid-open Application No. H5-21420

(Patent Document 6) Japanese Patent Laid-open Application No. 2002-280380

(Patent Document 7) Japanese Patent Laid-open Application No. 2005-268624

In case of heating the semiconductor wafer by using the electromagnetic wave as described above, the optical characteristics of the material disposed on the wafer surface may become less sensitive. However, in the above-described conventional methods, a pressure during the heating process and material properties of a semiconductor wafer itself are not sufficiently taken into consideration. Therefore, it is difficult to heat the wafer surface with a sufficient uniformity.

### SUMMARY OF THE INVENTION

It is, therefore, an object of the present invention to provide a heat treating apparatus and a heat treating method, and a storage medium, capable of rapidly raising or lowering a temperature without being influenced by the type of surface material of a target object while maintaining an in-surface uniformity of temperature.

In accordance with an aspect of the invention, there is provided a heat treating apparatus for performing a specified heat treatment on a target object, including a processing chamber accommodating therein the target object; a mounting table for mounting thereon the target object; a vacuum exhaust system for vacuum evacuating the processing chamber; an electromagnetic wave supply unit for irradiating an electromagnetic wave onto the target object to heat the target object; and a controller for controlling the heat treating apparatus such that the electromagnetic wave is irradiated onto the target object at a high vacuum level at which plasma is not generated.

With this configuration, the electromagnetic wave is irradiated on the target object under a high vacuum level at which plasma is not generated. Thus, the temperature can be rapidly raised or lowered without being influenced by the type of surface material of the target object while maintaining an in-surface uniformity of temperature, and the target object can be heated with a high efficiency.

It is preferable that the high vacuum level is equal to or lower than 1.3 Pa, or an irradiation energy of the electromagnetic wave per unit area of the target object is equal to or lower than 0.7 W/cm².

Further, it is preferable that the electromagnetic wave has a frequency within a range from 30 MHz to 300 THz.

Further, it is preferable that the frequency of the electromagnetic wave is set such that the target object is heated in a thickness direction and to a depth equal to half of that of the target object.

Further, it is preferable that the electromagnetic wave supply unit includes a planar antenna member having a plurality of slots.

Alternatively, it is preferable that the electromagnetic wave supply unit includes an upper electrode.

Further, it is preferable that the mounting table includes a temperature control unit having a plurality of thermoelectric conversion elements.

Further, it is preferable that the temperature control unit is partitioned into a plurality of regions, and a temperature of each of the regions is capable of being individually controlled.

Further, a SiON film may be formed on at least a part of a surface of the target object.

Further, water to be evaporated by heat may be attached to a surface of the target object.

Further, interstitial atoms, originated from impurities doped by ion implantation, may reside on a surface of the target object.

Further, two or more kinds of materials, whose optical characteristics are different from each other, may reside on a surface of the target object.

Further, an insulating film having a low dielectric constant may be formed on at least a part of a surface of the target object.

Further, a resist film may be formed on a surface of the target object.

In accordance with another aspect of the invention, there is provided a heat treating method of performing a specified heat treatment on a target object, wherein the target object is accommodated in a processing chamber capable of being vacuum evacuated, and the target object is heated by irradiating an electromagnetic wave thereon at a high vacuum level at which plasma is not generated in the processing chamber.

In accordance with still another aspect of the invention, there is provided a storage medium that stores therein a program for controlling a heat treating apparatus for performing a specified heat treatment on a target object, wherein the heat treating apparatus includes a processing chamber for accommodating therein the target object; a mounting table for mounting thereon the target object; a vacuum exhaust system for vacuum evacuating the processing chamber; an electromagnetic wave supply unit for irradiating an electromagnetic wave for heating onto the target object; and a controller for controlling the heat treating apparatus, and wherein the heat treating apparatus is controlled by the program such that the electromagnetic wave is irradiated onto the target object at a high vacuum level at which plasma is not generated.

The heat treating apparatus and method, and the storage medium of the present invention have the following advantageous effects.

By irradiating the electromagnetic wave on the target object under a high vacuum level at which plasma is not generated, the temperature can be rapidly raised or lowered without being influenced by the type of surface material of the target object while maintaining an in-surface uniformity of temperature, and the target object can be heated with a high efficiency.

### BRIEF DESCRIPTION OF THE DRAWINGS

The above and other objects and features of the present invention will become apparent from the following description of embodiments given in conjunction with the accompanying drawings, in which:

FIG. 1 provides a schematic cross sectional view of a heat treating apparatus in accordance with a first embodiment of the present invention;

FIG. 2 shows a cross sectional view depicting an arrangement of thermoelectric conversion elements;

FIGS. 3A and 3B present examples of partitioning heating regions of a mounting table;

FIG. 4 is a flow chart showing an example of the heat treating method of the present invention;

FIGS. 5A and 5B provide graphs representing a relationship between a frequency of an electromagnetic wave and a power penetration depth with respect to a conductor and an insulator, respectively; and

FIG. 6 provides a schematic cross sectional view of a heat treating apparatus in accordance with a second embodiment of the present invention.

### DETAILED DESCRIPTION OF THE EMBODIMENTS

Hereinafter, a heat treating apparatus, a heat treating method, and a storage medium in accordance with the present invention will be described in detail with reference to the accompanying drawings.

### First Embodiment

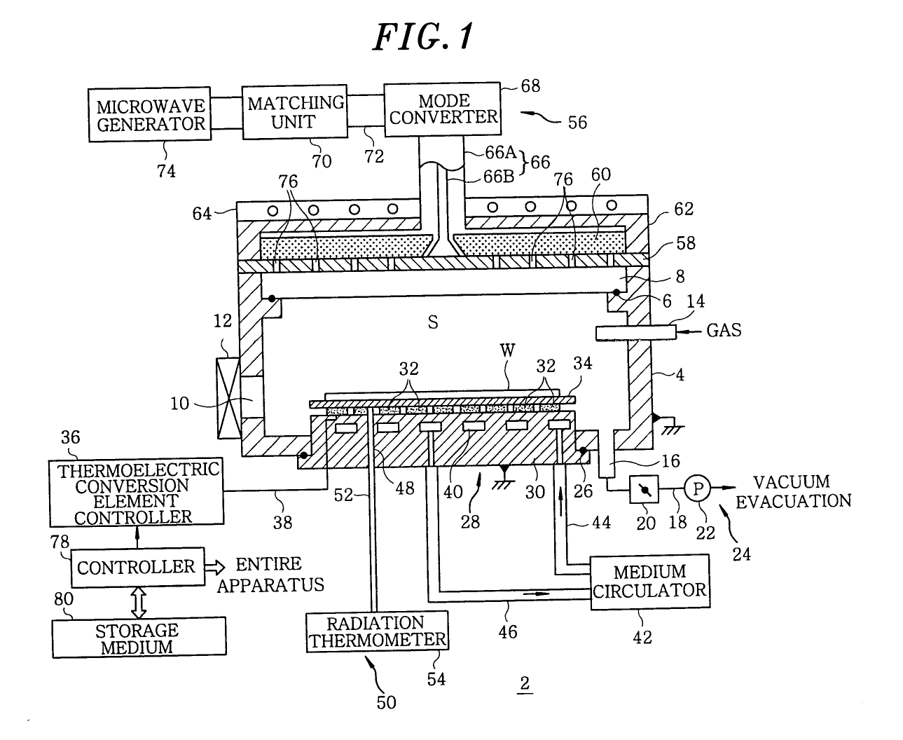

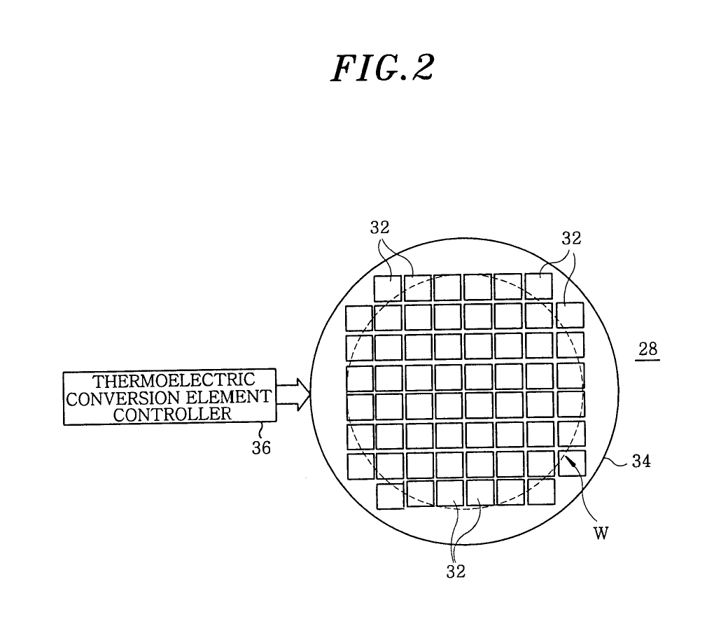

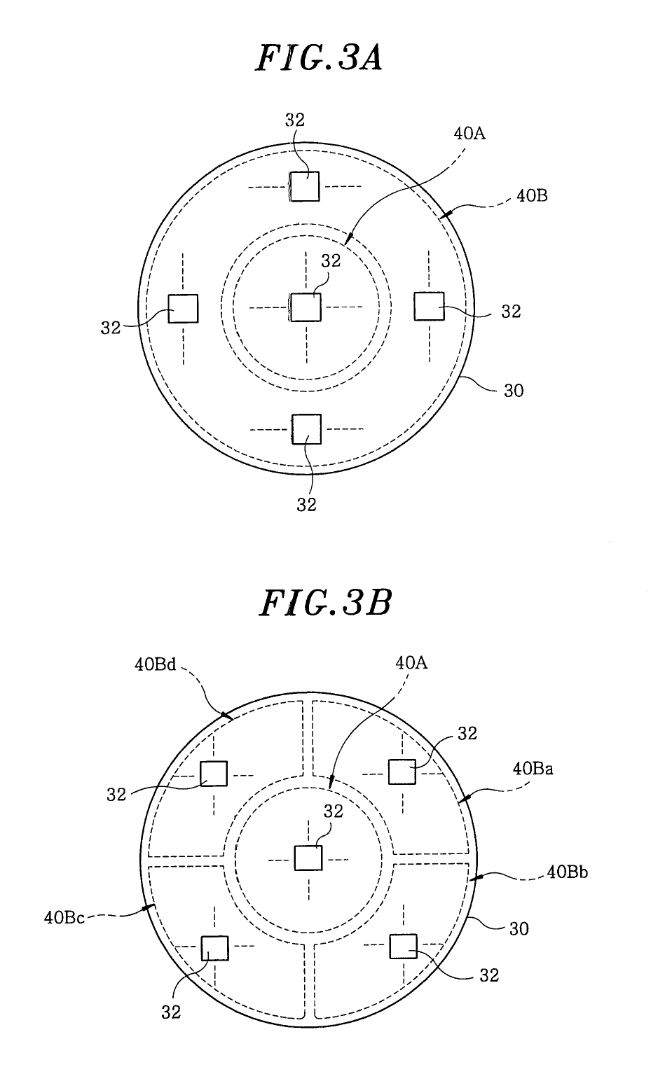

FIG. 1 provides a schematic cross sectional view of a heat treating apparatus in accordance with a first embodiment of the present invention, FIG. 2 shows a cross sectional view depicting an arrangement of thermoelectric conversion elements, and FIGS. 3A and 3B present examples of partitioning heating regions of a mounting table.

As shown in FIG. 1, a heat treating apparatus 2 of the first embodiment includes, for example, a processing chamber of a housing shape made of aluminum. The processing chamber 4 is of a size capable of accommodating a semiconductor wafer having a diameter of, for example, 300 mm that is a substrate serving as a target object. The processing chamber 4 itself is grounded. A ceiling portion of the processing chamber 4 is opened. In this opening, a ceiling plate 8 for transmitting an electromagnetic wave, that will be described later, is airtightly installed by means of a sealing member 6 such as an O-ring or the like. The ceiling plate 8 is made of ceramic, e.g., quartz, aluminum nitride or the like.

Further, an opening 10 is formed on a sidewall of the processing chamber 4, and a gate valve 12 is disposed on the opening 10 to be opened and closed when the target object such as a semiconductor wafer W is loaded or unloaded. Further, provided on the other sidewall of the processing chamber 4 is a gas nozzle 14 serving as a gas introduction unit for introducing thereto a processing gas when necessary. Formed in the vicinity of the bottom portion of the processing chamber 4 is a gas exhaust port 16, to which is connected a vacuum exhaust system 24 configured by installing a pressure control valve 20, a vacuum pump 22 and the like at an exhaust passage 18. Thus, the atmosphere in the processing chamber 4 can be vacuum evacuated. Further, the bottom portion of the processing chamber 4 is opened widely, and a thick mounting table 28, that serves as a bottom portion as well, is airtightly attached to the opening by interposing a sealing member 26 such as an 0-ring or the like therebetween. The mounting table 28 is also grounded.

The mounting table 28 includes a thick mounting table main body 30 made of, e.g., aluminum; a plurality of thermoelectric conversion elements 32 serving as a temperature control unit disposed on an upper portion of the mounting table main body 30; and a thin mounting plate 34 of a circular plate shape installed on a top surface of the thermoelectric conversion elements 32, wherein the semiconductor wafer W serving as the target object is to be mounted directly on the mounting plate 34.

To be more specific, for example, Peltier elements can be used as the thermoelectric conversion elements 32. The Peltier element is an element in which, if different kinds of conductors or semiconductors are connected in series by an electrode, and then an electric current is made to flow therethrough, heat other than Joule heat is generated or absorbed at the contacts. The Peltier element is formed of, e.g., Bismuth Telluride (Bi₂Te₃) that can be used up to 200° C., lead telluride (PbTe) or silicon germanium (SiGe) that can be used up to a higher temperature, or the like. Here, the Peltier elements are electrically connected to a thermoelectric conversion element controller 36 via a lead line 38. The thermoelectric conversion element controller controls the direction and the amount of the electric current supplied to the thermoelectric conversion element when heat-treating the wafer W.

FIG. 2 shows an example of the arrangement of the thermoelectric conversion elements 32 formed of Peltier elements. As shown therein, for the wafer W having a diameter of 300 mm, sixty thermoelectric conversion elements cover an almost entire part of a rear surface of the mounting plate 34 (i.e. a top surface of the mounting table main body 30). By arranging the thermoelectric conversion elements 32 to be close to each other in this manner, the wafer W and the mounting plate 34 can be heated uniformly. Each of the thermoelectric conversion elements 32 is not limited to a square shape, and it may be of a circular or a hexagonal shape. Herein, the thermoelectric conversion refers to converting thermal energy into electric energy or vice versa.

Herein, the temperature of the thermoelectric conversion elements 32 may be collectively controlled. Alternatively, the thermoelectric conversion elements 32 may be grouped into a plurality of heating regions, so that each of the heating regions may be temperature-controlled individually and independently. As an example of the grouping that is shown in FIG. 3A, the thermoelectric conversion elements 32 can be grouped into two heating regions, for example, an inner region 40A and an outer region 40B whose boundaries form concentric circles.

Alternatively, as shown in FIG. 3B, the outer region may be divided into a plurality of sub-regions, each of which formed in a circular arc shape. For example, the outer region may be divided it into quarters, i.e. four sub-regions 40Ba, 40Bb, 40Bc, and 40Bd. Herein, the number or the shape of the region is not limited to a specific number or shape. Furthermore, the thermoelectric conversion elements 32 serving as the temperature control unit may be provided only if necessary, and may be omitted if it is sufficient to heat the target object only by the electromagnetic wave that will be described later.

Return to FIG. 1, a heat transfer medium path 40 is formed inside the mounting table main body 30 over the almost entire surface in a plane direction thereof. The heat transfer medium path 40 is installed below the thermoelectric conversion elements 32. When lowering the temperature of the wafer W, the heat transfer medium path 40 cools down the bottom surface of the thermoelectric conversion elements 32 by taking heat therefrom by supplying a cooling medium as a heat transfer medium therethrough. Further, when raising the temperature of the wafer W, according to need, a heating medium is supplied to take cold heat from the bottom surface of the thermoelectric conversion element 32, thereby heating the bottom surface of the thermoelectric conversion element 32.

The heat transfer medium path 40 is connected to a medium circulator 42 for supplying a heat transfer medium via a heat transfer medium inlet line 44 and a heat transfer medium discharge line 46, whereby the medium circulator 42 circulates and supplies the heat transfer medium to the heat transfer medium path 40.

Furthermore, the mounting plate 34 installed on the thermoelectric conversion element 32 is made of SiO₂, AlN, SiC, Ge, Si, metal and/or the like. Further, the mounting table 28 is provided with an elevating mechanism (not shown) for vertically moving the wafer W, which includes a plurality of elevatable supporting pins for supporting the wafer W from its bottom surface by penetrating through the mounting table main body 30 and the mounting plate 34, and a driving unit for vertically moving the supporting pins. Further, an electrostatic chuck may be installed at the mounting plate 34.

Moreover, formed at the mounting table main body 30 is a through hole 48 vertically penetrating therethrough, where a radiation thermometer 50 is installed. More specifically, an optical fiber 52 is airtightly inserted into the through hole 48 to guide a radiant light from the mounting plate 34, wherein the optical fiber 52 is extended to the bottom surface of the mounting plate 34. Further, a radiation thermometer main body 54 is connected to the other end portion of the optical fiber 52, so that the temperature of the mounting plate 34, i.e. the temperature of the wafer, can be measured by measuring light within a specified wavelength band.

Further, installed above the ceiling plate 8 of the processing chamber 4 is an electromagnetic wave supply unit for irradiating, onto the wafer W, an electromagnetic wave for heating. Herein, the electromagnetic wave may have a frequency within a range from 30 MHz to 300 THz. In general, the boundary between the high frequency wave and the microwave is located at 300 MHz or 1 GHz. Hereinafter, an example using a microwave of 2.45 GHz will be described.

To be specific, the electromagnetic wave supply unit 56 includes a disc-shaped planar antenna member 58 provided on a top surface of the ceiling plate 8, and a wave-delay member 60 is formed on the planar antenna member 58. The wave-delay member 60 has a high dielectric constant to shorten the wavelength of the microwave. The planar antenna member 58 is formed as a bottom plate of a waveguide box 62, the waveguide box 62 being formed of a hollow conductive cylindrical container covering the entire top surface of the wave-delay member 60. Further, the planar antenna member 58 is arranged to face the mounting table 28 in the processing chamber 4. A cooling jacket 64 is installed in an upper portion of the waveguide box 62 for cooling down the waveguide box 62 by allowing a coolant to flow therethrough.

Peripheral portions of the waveguide box 62 and the planar antenna member 58 are electrically connected to the processing chamber 4. Further, an outer tube 66A of a coaxial waveguide 66 is connected to an upper central portion of the waveguide box 62, and an internal conductor 66B is connected to a central portion of the planar antenna member 58 through a through hole formed at a central portion of the wave-delay member 60. Besides, the coaxial waveguide 66 is connected to a microwave generator 74 for generating a microwave of, e.g., 2.45 GHz, via a matching circuit 70, a mode converter 68 and a waveguide 72 to thereby transfer the microwave as the electromagnetic wave to the planar antenna member 58. The frequency thereof is not limited to 2.45 GHz, and it may be 28 GHz, 100 GHz or 1 THz. Further, a waveguide with a circular cross section, a rectangular waveguide, or a coaxial waveguide may also be used as the waveguide 72. Furthermore, the wave-delay member 60 may be formed of, e.g., aluminum nitride.

In case of using a wafer with a diameter of 300 mm, the planar antenna member 58 is, for example, made of a circular conducting plate, e.g., a copper plate with a silver-plated surface or an aluminum plate, wherein the circular plate has a diameter within a range from 400 mm to 500 mm and a thickness more than or equal to 1 mm and less than 10 mm. Furthermore, the circular plate is provided with a plurality of microwave radiation holes 76, each of which is formed of a through hole in a long groove shape. The arrangement of the microwave radiation holes 76 is not limited to a specific form, and may be formed in, e.g., a concentric circular shape, a spiral shape or a radial shape. Alternatively, the holes 76 may be distributed uniformly across the entire surface of the antenna member. In many cases, two microwave radiation holes 76 are disposed in a T-shape with a slight gap therebetween to form a pair of holes, and the pair of holes is arranged in a concentric circular shape. In this manner, the planar antenna member 58 is configured as an RLSA (Radial Line Slot Antenna) type antenna.

Meanwhile, the operation of the entire heat treating apparatus 2 is controlled by a controller 78 configured by, e.g., a microcomputer. A computer program for executing the operation is stored in a storage medium 80 such as a floppy disc, a CD (compact disc), a flash memory or the like. Specifically, in response to instructions from the controller 78, a supply or a flow rate of gas, a supply or a power of microwave, a processing temperature or pressure, and the like are controlled.

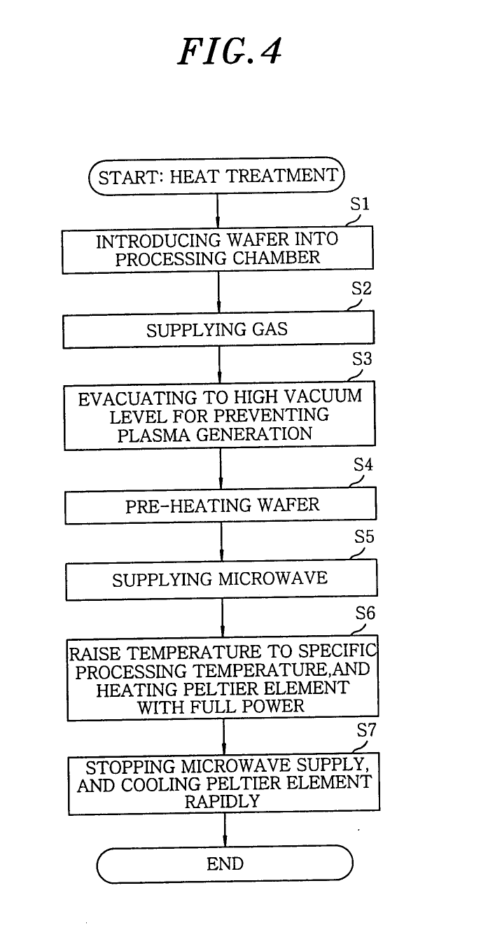

Hereinafter, a heat treating method using the heat treating apparatus 2 as configured above (more particularly, an annealing method) will be now described with reference to FIG. 4, which is a flow chart showing an example of the heat treating method of the present invention.

First, the semiconductor wafer W is introduced into the processing chamber 4 by a transfer arm (not shown) via the gate valve 12 (step S1), and then mounted on the mounting plate 34 of the mounting table 28 by vertically moving elevating pins (not shown). Then, the gate valve 12 is closed to seal the processing chamber 4. Next, the processing chamber 4 is vacuum evacuated by the vacuum exhaust system 24, and, when necessary, provided with a certain amount of inert gas such as an argon gas or a nitrogen gas through the gas nozzle 14 (step S2), whereby the processing chamber 4 is maintained at a specified processing pressure, i.e. at a high vacuum level at which plasma is not generated, e.g., at 1.3 Pa or below (step S3).

Next, an electric current is applied to the thermoelectric conversion elements 32 formed of the Peltier elements, whereby the wafer W is pre-heated (step S4). The wafer W is pre-heated at a temperature within a range from about 500° C. to about 600° C., at which impurities implanted in the wafer W do not diffuse.

The temperature of the wafer W is detected by the radiation thermometer 50. If radiation thermometer 50 detects that the wafer W reaches a specific pre-heating temperature, the microwave generator 74 in the electromagnetic wave supply unit 56 is operated, so that a microwave is generated from the microwave generator 74. The microwave is supplied to the planar antenna member 58 via the waveguide 72 and the coaxial waveguide 66. Thereafter, a microwave whose wavelength has been shortened by the wave-delay member 60 is radiated through the microwave radiation holes 76 and then introduced into a processing space S after being transmitted through the ceiling plate 8. The microwave introduced into the processing space S is radiated onto the surface of the wafer W, so that this surface is rapidly heated by electromagnetic wave heating (step S5).

Thereby, the temperature of the surface of the wafer W is instantaneously raised to a specific processing temperature (e.g., 1000° C.) (step S6). At this time, a full power is supplied to the thermoelectric conversion elements to rapidly raise the temperature of the wafer W. The annealing process is performed while maintaining the high temperature state for a specific period of time. Accordingly, by heating the wafer W from the upper and lower side thereof, the temperature elevation rate can be up to, e.g., 100° C./sec˜200° C./sec to thereby realize a high-speed temperature elevation.

In this case, a visible ray or an ultraviolet light is not used for heating. Therefore, although there are minute areas formed of materials having optical characteristics different from each other on the surface of the wafer W, the annealing can be performed by selectively and rapidly raising the temperature of the wafer surface. In other words, since a flash lamp annealing or a laser annealing in the conventional apparatus uses a wave with a short wavelength, an absorption state of light energy vary depending on the optical characteristics (e.g., a reflectance, an absorptance and a transmittance) of the surface material. Therefore, a uniform heating is not possible because of the influence of patterns having depths of as small as even 1 μm. However, in accordance with the present invention, the heating is performed by using the electromagnetic wave with a longer wavelength, whereby the energy can be absorbed over the entire wafer surface to a depth of about 325 μm to about 400 μm from the wafer surface. Accordingly, the pattern dependence can be avoided, thereby making it possible to selectively and uniformly heat the surface. In this manner, the in-surface uniformity can be enhanced.

Thus, since lattice atoms can be activated without diffusing interstitial atoms originated from ion-implanted impurities, the energy can be used efficiently. Further, since the surface of the wafer W can be selectively heated, heating energy can be reduced, thereby contributing to energy saving. If, for example, the frequency of the microwave is set such that the microwave heats the wafer W in a thickness direction and to a depth equal to half of that of the wafer W, it is possible to raise the temperature of only the surface portion of the wafer W more rapidly. Further, when raising the temperature of the wafer, the thermoelectric conversion elements 32 function as a heating unit for the lower part.

In this annealing process, cold heat is generated from the rear surface of the thermoelectric conversion elements 32 formed of the Peltier elements. In order to discharge the cold heat, it is preferable that a heating medium is made to flow through the heat transfer medium path 40 disposed in the mounting table main body 30 to thereby efficiently operate the thermoelectric conversion elements 32.

After completing the annealing process for a specific short period of time, the wafer W is cooled as quickly as possible in order to prevent the impurities in the wafer W from excessively diffusing. In this case, in order to lower the temperature of the wafer at a high speed, the microwave generator 74 stops generating the microwave, and an electric current is made to flow through the thermoelectric conversion elements 32 formed of the Peltier elements in a direction opposite to that during the heating to thereby cool the top surface of each of the thermoelectric conversion elements 32.

Thus, the mounting plate 34 is cooled down to rapidly cool the wafer W (step S7). At this time, the bottom surface of each of the thermoelectric conversion elements 32 is heated from the thermal energy generated therefrom. In order to cool this down, contrary to the case of heating the wafer, a cooling medium is made to flow through the heat transfer medium path 40. In this manner, the thermoelectric conversion elements 32 are operated efficiently to enhance the temperature lowering speed of the wafer W, thereby realizing a high-speed temperature reduction. In accordance with the present invention, the temperature of the wafer can be lowered at a high reduction rate of, e.g., 100° C./sec to 300° C./sec.

In the above annealing process, if the pressure in the processing chamber 4 becomes higher than 1.3 Pa, plasma is generated to rapidly deteriorate the heating efficiency of the wafer, which is not desirable. However, even when the pressure in the processing chamber 4 is higher than 1.3 Pa, if the irradiation energy of the electromagnetic wave per unit area of the target object is not greater than 0.7 W/cm², plasma is not generated. On the contrary, even when the irradiation energy of the electromagnetic wave per unit area of the target object is greater than 0.7 W/cm², if the pressure of the processing chamber 4 is not greater than 1.3 Pa, plasma is not generated, either.

Herein, the electromagnetic wave having a frequency within a range from 30 MHz to 300 THz is used for heating. However, considering physical properties (e.g., a dielectric constant, a dielectric loss, an electrical resistance, a relative permeability and the like) the target object or the thickness of the target object, a frequency of the electromagnetic wave is preferably within a range from 300 MHz to 30 THz, and more preferably, within a range from 1 THz to 5 THz.

The reason why the frequency of the electromagnetic wave is set such that almost only an upper half region of the wafer W can be heated in the thickness direction is because, in case of using a wafer with a diameter of 300 mm, the annealing process for the target region can be adequately performed by heating the wafer to its half depth. On the other hand, if the frequency of the electromagnetic wave is set such that the whole thickness of the wafer W is heated, other objects than the wafer, e.g. the mounting table 28 for mounting the wafer thereon, are heated together to a certain degree, thereby deteriorating the energy efficiency. Since the wafer W with a diameter of, e.g., 300-mm usually has a thickness of 700 μm, the wafer is set to be heated to its half depth (i.e., to 350 μm) in this example. However, regardless of the thickness of the wafer, if the wafer can be heated to a 350 μm depth from its surface, the annealing process can be adequately performed.

(Frequency Evaluation of the Electromagnetic Wave)

Hereinafter, there will be described evaluation results of the simulation for the frequency optimization in case of microwave-heating the semiconductor wafer.

In this simulation, since mathematical equations used for simulating the semiconductor are not known, and the semiconductor has physical properties between the conductor and the insulator, both the conductor such as a metal and the insulator was evaluated, and an intermediate range therebetween was considered to be an optimal range for the semiconductor.

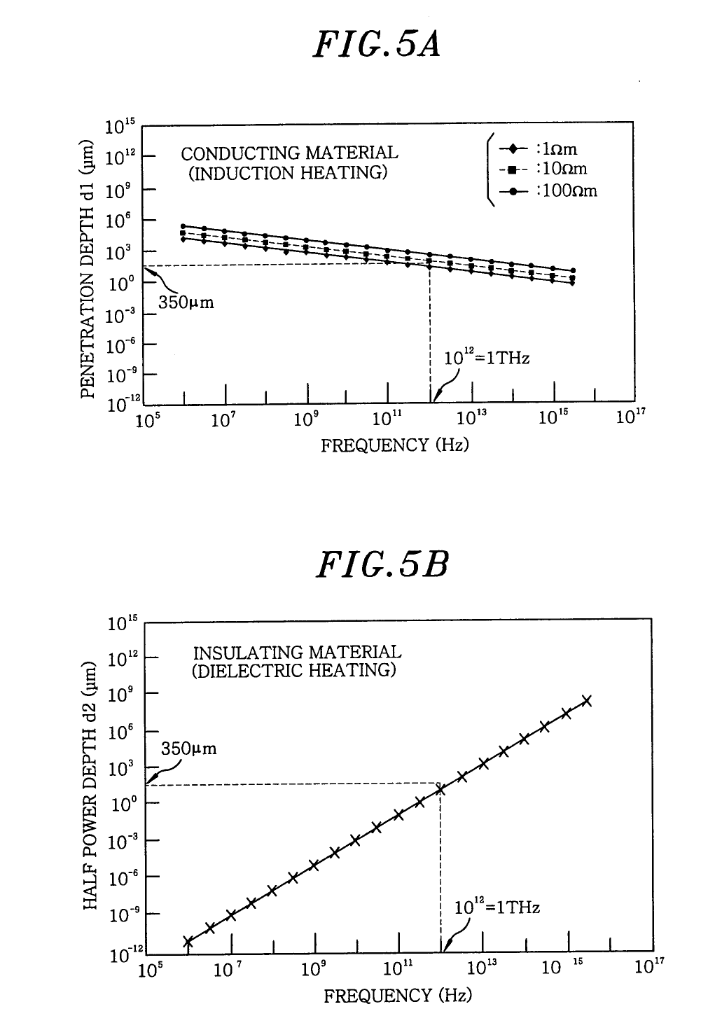

FIGS. 5A and 5B provide graphs representing relationships between the frequency of the electromagnetic wave and the power penetration depth with respect to the conductor and the insulator, respectively. FIG. 5A is a graph showing a case where a conducting material was heated by induction heating, and FIG. 5B is a graph showing a case where an insulating material was heated by dielectric heating.

FIG. 5A illustrates the depth of the power penetrated a sample of conducting material in a thickness direction thereof, wherein the sample of conducting material had a thickness of 0.7 mm (equal to that of the semiconductor wafer), and a relative permeability μ thereof was fixed to 1. Herein, three magnitudes of resistivity ρ, i.e. 1 Ωcm, 10 Ωcm and 100 Ωcm, were considered. Furthermore, the frequency f was set to vary from about 10⁶ Hz to about 10¹⁵ Hz. The penetration depth d1 can be obtained as follows:

d1=5.03×10⁷×√(p/(μ·f)) (Eq. 1)

As is clear from FIG. 5A, as the frequency increased approximately from 10⁶ Hz to 10¹⁵ Hz, the penetration depth decreased almost linearly from about 10⁵ μm to about 10⁰ μm, regardless of the magnitude of resistivity ρ.

Herein, the frequency f when the power penetrated to 0.35 mm (350 μm) in depth, i.e. half of the thickness (0.7 mm) of the conducting material sample, was approximately 1 THz. In other words, in case of the conductor, it was verified that the frequency is required to be equal to or lower than 1 THz in order for the electromagnetic wave to penetrate into 0.35 mm or more in depth.

On the contrary, FIG. 5B illustrates the depth of the power penetrated in a thickness direction of a sample of insulating material, wherein the insulator sample had a thickness of 0.7 mm. Herein, a relative permittivity ε and a dielectric loss tan δ were variables. Further, the frequency f was set to vary from about 10⁶ Hz to about 10¹⁵ Hz. A half power depth d2 can be obtained as follows:

d2=3.32×10¹³/(f√(ε)·tan δ) (Eq. 2)

As can be seen in FIG. 5B, although √/(ε)·tan δ was a variable, all the graphs were found to be same. As is clear therefrom, as the frequency increased approximately from 10⁶ Hz to 10¹⁵ Hz, the half power depth increased almost linearly from about 10⁻¹¹ μm to about 10⁹ μm regardless of the magnitude of √(ε)·tan δ, which was in contrast to the case of FIG. 5A. Herein, the frequency f at the half power depth of 0.35 mm (350 μm), i.e. half of the thickness (0.7 mm) of the insulator sample was approximately 5 THz (=5×10¹² Hz). In other words, in case of the insulator, it was verified that the frequency is required to be equal to or greater than about 5 THz in order for the electromagnetic wave to penetrate into 0.35 mm or more in depth.

In conclusion, it was deduced that, in case of the semiconductor wafer (e.g., a silicon substrate) whose physical properties are in an intermediate range between the conductor and the insulator, an upper half portion (about 0.35 mm thick) of the semiconductor wafer can be selectively heated by using the electromagnetic wave whose frequency lies between the above two cutoff frequencies, preferably, in the range from 1 THz to 5 THz.

Herein, the reason why the wafer is set to be heated to a depth equal to half of that of the wafer is because the range of depth of ion implantation can be sufficiently covered by heating the wafer only to about 0.35 mm in depth. For example, even when using a wafer having a thickness of 2 mm, it is sufficient to heat the wafer to 0.35 mm in depth from its surface. In practice, in case of heat-treating the wafer by the electromagnetic wave, it is more preferable to further narrow the frequency range within the above range of 1 THz to 5 THz by considering the physical properties.

(Verification Experiment of the Heating Efficiency)

Next, the experiment results of performing the heat treatment on the wafer by using the electromagnetic wave will be described in comparison with a case of using a conventional heating apparatus employing a halogen lamp.

In this experiment, a 5-inch wafer was heated by using a microwave (electromagnetic wave) of 2.45 GHz, and the following results were obtained: the temperature elevation rate was 35° C./sec, the power consumption was 1.24 kW, and the power density per unit area is 1.18 W/cm². Therefore, the heating efficiency A in this experiment was calculated as follows:

Heating efficiency A=35/1.18=29 (Eq. 3)

Further, in a comparative experiment, a 300-mm diameter wafer was heated by using a heating apparatus employing a halogen lamp, and the following results were obtained: the temperature elevation rate was 100° C./sec, the power consumption was 186 kW, and the power density per unit area was 263 W/cm². Therefore, the heating efficiency B was calculated as follows:

Heating efficiency B=100/263=0.38 (Eq. 4)

In conclusion, by comparing the respective magnitudes of heating efficiency (that is equal to the temperature elevation rate divided by the power density per unit area), it was verified that the present invention was about 76 (29/0.38) times superior in the heating efficiency.

### Second Embodiment

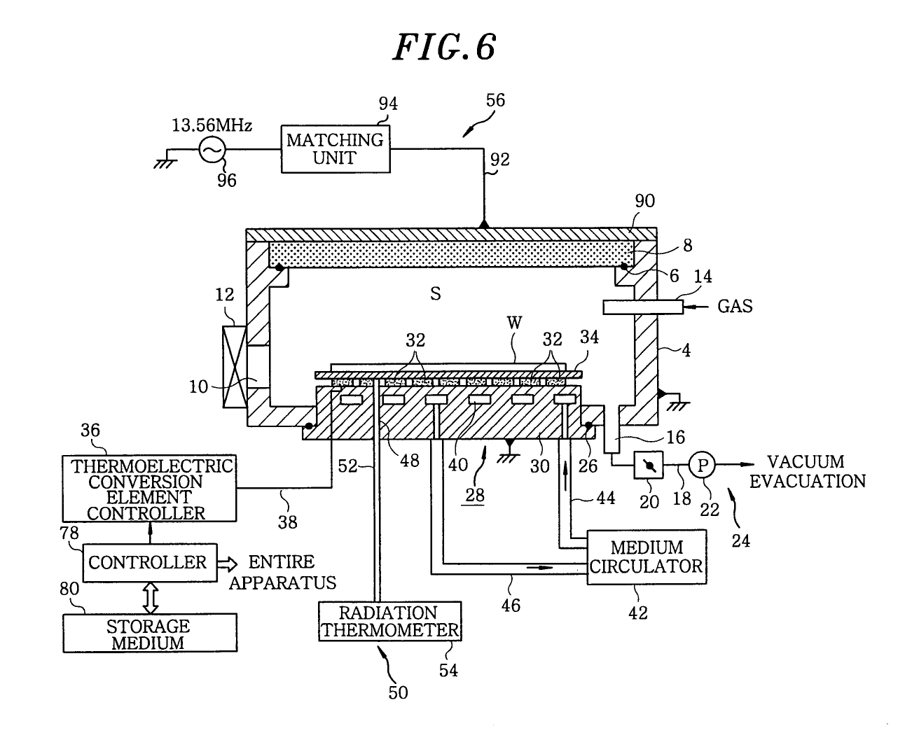

Hereinafter, the second embodiment of the present invention will be described. FIG. 6 provides a schematic cross sectional view of a heat treating apparatus in accordance with the second embodiment of the present invention, wherein same reference numerals are used for same parts as those shown in FIG. 1. In the following, descriptions of same parts as those described above will be omitted.

Whereas the first embodiment has been described with respect to a case of using the electromagnetic wave within a microwave band, the present embodiment will be described with respect to a case of using the electromagnetic wave within a high frequency band. Although the boundary between the high frequency wave and the microwave is usually located at about 300 MHz, the frequency of the high frequency wave should not be construed to be limited thereto. In the present embodiment, a high frequency of 13.56 MHz is used.

In FIG. 1, the planar antenna member 58 is provided with the plurality of microwave radiation holes 76 in order to radiate the microwave. However, in case of using the high frequency wave, an upper electrode 90 of a circular plate shape is formed on the ceiling plate 8 as a part of the electromagnetic wave supply unit 56, wherein the upper electrode 90 is made of the same material as that of the planar antenna member 58. In this case, the mounting table functions as a lower electrode, thereby forming a parallel plate type heat treating apparatus.

Besides, a coaxial cable 92, which is connected to the upper electrode 90, is in turn connected to a high frequency power supply 96, whose frequency is 13.56 MHz for example, via a matching circuit 94. Further, the frequency of the high frequency wave is not limited to 13.56 MHz, and may be set within a range from 30 MHz to 300 MHz.

The heat treating apparatus of the present embodiment has operational effects same as those of the first embodiment shown in FIGS. 1 to 5, except for the fact that an electromagnetic wave in a different frequency band is used in the present embodiment.

Furthermore, the following conditions are exemplified as the state of the semiconductor wafer in case of heat-treating the semiconductor wafer W serving as the target object, which is an object to be heated in the above embodiments.

### (1) Annealing Module for a SiON Film on a Surface of a Semiconductor Wafer

If a SiON film is formed on the wafer surface, the wafer surface is selectively heated by the above-mentioned electromagnetic wave heating to thereby resurface or stabilize the N-atom distribution, thus improving the film characteristics.

### (2) Selective Annealing Module for a Pure Water Component on a Surface of a Semiconductor Wafer

In a baking process of a PEB (Post Exposure Bake) module, a liquid immersion and exposure process is to be performed later. In this case, pure water remaining on the wafer surface can be selectively heated and evaporated. Further, in a drying module, dilution water that remains on the wafer surface after a cleaning process can be dried out by the electromagnetic wave heating without remaining a watermark.

### (3) Annealing Module for an Insulating Layer of a Low Dielectric Constant (Low-K)

Currently, in the development of a low-k insulating layer, there are problems in improving an adhesion of a base layer as well as lowering the dielectric constant. However, for example, in case of using a compound material having a Si—O—Si bond structure such as siloxane, if an electromagnetic wave whose absorption wavelength of 9 μm (33 THz) that is characteristic to the Si—O—Si bond is irradiated on the insulating film, chemical compounds are generated by being reacted with the base layer interface. Thus, the material characteristics, as well as the adhesion of the base layer, can be improved.

(4) Selective annealing module for a chemical amplification resist layer on a top surface of a wafer

In the recent development of photo-lithographic processes, there are problems of, in addition to pattern collapse, CD (Critical Dimension) loss reduction. However, for example, by irradiating the electromagnetic wave whose absorption wavelength is 9 μm (that is equivalent to 33 THz) onto a polymer material used for a resist having a Si—O—Si bond structure, the cross-linking density is stabilized. Thus, the resist PEB (Post Exposure Bake) sensitivity can be made lower. As a result, the CD is stabilized against the temperature change, thereby improving the material characteristics.

Although the above embodiments have been described with respect to the semiconductor wafer as the substrate serving as the target object, the present invention is not limited thereto, and may be applied to a glass substrate, an LCD substrate, a ceramic substrate or the like.

While the invention has been shown and described with respect to the embodiments, it will be understood by those skilled in the art that various changes and modifications may be without departing from the scope of the invention as defined in the following claims.

What is claimed is:

1. A heat treating method of performing a specified heat treatment on a target object,
wherein the target object is accommodated in a processing chamber capable of being vacuum evacuated,
wherein the target object is heated by irradiating an electromagnetic wave thereon at a high vacuum level at which plasma is not generated in the processing chamber,
wherein the target object is a semiconductor wafer,
wherein the electromagnetic wave has a frequency within a range from 1 to 5 THz, and
wherein the electromagnetic wave penetrates to a depth of 0.35 mm from a surface of the target object on which the electromagnetic wave is irradiated.

2. The heat treating method of claim 1, wherein the high vacuum level is equal to or lower than 1.3 Pa.

3. The heat treating method of claim 1, wherein an irradiation energy of the electromagnetic wave per unit area of the target object is equal to or lower than 0.7 W/cm².

4. The heat treating method of claim 1, wherein interstitial atoms, originated from impurities doped by ion implantation, reside on a surface of the target object.

5. The heat treating method of claim 1, wherein a SiON film is formed on at least a part of a surface of the target object.

6. The heat treating method of claim 2, wherein an irradiation energy of the electromagnetic wave per unit area of the target object is equal to or lower than 0.7 W/cm².

7. The heat treating method of claim 2, wherein interstitial atoms, originated from impurities doped by ion implantation, reside on a surface of the target object.

8. The heat treating method of claim 2, wherein a SiON film is formed on at least a part of a surface of the target object.

9. The heat treating method of claim 3, wherein interstitial atoms, originated from impurities doped by ion implantation, reside on a surface of the target object.

10. The heat treating method of claim 3, wherein a SiON film is formed on at least a part of a surface of the target object.

11. The heat treating method of claim 4, wherein a SiON film is formed on at least a part of a surface of the target object.

12. The heat treating method of claim 6, wherein interstitial atoms, originated from impurities doped by ion implantation, reside on a surface of the target object.

13. The heat treating method of claim 6, wherein a SiON film is formed on at least a part of a surface of the target object.

14. The heat treating method of claim 7, wherein a SiON film is formed on at least a part of a surface of the target object.

15. The heat treating method of claim 9, wherein a SiON film is formed on at least a part of a surface of the target object.

16. The heat treating method of claim 12, wherein a SiON film is formed on at least a part of a surface of the target object.
